(19) United States
(12) Patent Application Publication
(10) Pub. No.: US 2024/0136474 A1
(43) Pub. Date: Apr. 25, 2024

(54) METHOD OF MANUFACTURING DISPLAY DEVICE AND DISPLAY DEVICE

(71) Applicant: Samsung Display Co., LTD., Yongin-si (KR)

(72) Inventors: Ji Yun BANG, Yongin-si (KR); Jung Wook KIM, Yongin-si (KR); Hee Chang KIM, Yongin-si (KR); Eun Joong MUN, Yongin-si (KR); Kyoung Hee PARK, Yongin-si (KR); Hyeon Deuk HWANG, Yongin-si (KR)

(73) Assignee: Samsung Display Co., LTD., Yongin-si (KR)

(21) Appl. No.: 18/328,922

(22) Filed: Jun. 4, 2023

(30) Foreign Application Priority Data
Oct. 23, 2022 (KR) 10-2022-0137760

(51) Int. Cl. H01L 33/44

(52) U.S. Cl. CPC H01L 33/44; H01L 2933/0025

(57) ABSTRACT

A method of manufacturing a display device includes providing an adhesive material layer on a display panel, curing the adhesive material layer to form an adhesive layer, providing a cover layer on the adhesive layer, and adhering the cover layer to the adhesive layer, and a modulus of the adhesive layer at room temperature is in a range of about 10³ Pa to about 10⁶ Pa.

### CROSS-REFERENCE TO RELATED APPLICATION

This application claims priority to and benefits of Korean Patent Application No. 10-2022-0137760 under 35 U.S.C. § 119, filed in the Korean Intellectual Property Office on Oct. 24, 2022, the entire contents of which are incorporated herein by reference.

### BACKGROUND

### 1. Technical Field

The disclosure relates to a method of manufacturing a display device and a display device which is capable of preventing an adhesion defect and a discoloration defect.

### 2. Description of the Related Art

The importance of display devices has been emphasized because of the increasing developments of information technology.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a method of manufacturing a display device, which is capable of minimizing or preventing an adhesion defect of a cover layer of a curved surface and a discoloration defect of a light blocking layer.

Embodiments also provide a display device which is capable of minimizing or preventing an adhesion defect of a cover layer of a curved surface and a discoloration defect of a light blocking layer.

However, embodiments of the disclosure are not limited to those set forth herein. The above and other embodiments will become more apparent to one of ordinary skill in the art to which the disclosure pertains by referencing the detailed description of the disclosure given below.

According to embodiments of the disclosure, a method of manufacturing a display device includes providing an adhesive material layer on a display panel, curing the adhesive material layer to form an adhesive layer, providing a cover layer on the adhesive layer, and adhering the cover layer to the adhesive layer, and a modulus of the adhesive layer at room temperature is in a range of about 10³ Pa to about 10⁶ Pa.

The cover layer may include a curved surface.

A viscosity of the adhesive material layer may be in a range of about 1 cps to about 30 cps at room temperature.

A peel strength of the adhesive layer at room temperature may be about 2,000 gf/in or greater.

A surface curing rate of the adhesive layer may be about 85% or greater.

A deep curing rate of the adhesive layer is about 85% or greater.

The adhesive material layer may be provided on the display panel in a liquid state.

The adhesive layer may be in a semi-solid state.

The adhesive material layer may be cured in an exposed state.

The method may further include forming a light blocking layer on the display panel.

The curing of the adhesive material layer may include irradiating an ultraviolet light onto the adhesive material layer.

The curing of the adhesive material layer may include applying a heat to the adhesive material layer.

According to embodiments of the disclosure, a display device includes a display panel, an adhesive layer on the display panel, a cover layer on the adhesive layer, and a light blocking layer between the adhesive layer and the cover layer, and a surface curing rate of a first area of the adhesive layer overlapping the light blocking layer in a plan view is equal to a surface curing rate of a second area of the adhesive layer which is not overlapping the light blocking layer in a plan view.

The cover layer may include a curved surface.

A modulus of the adhesive layer may be in a range of about 10³ Pa to about 10⁶ Pa at room temperature.

A peel strength of the adhesive layer at room temperature may be about 2,000 gf/in or greater.

A surface curing rate of the adhesive layer may be about 85% or greater.

The adhesive layer may be in a semi-solid state.

The adhesive material layer may include a photocurable acrylic resin, a photoinitiator, a coupling agent, a radical generator, and a solvent.

The adhesive material layer may include a thermosetting acrylic resin, a heat curing agent, a coupling agent, and a solvent.

The details of other embodiments are included in the detailed description and drawings.

According to the above-described embodiment, curing may be performed (or completed) before the adhesive layer is bonded to the light blocking layer and/or the cover layer, and the adhesive layer may have adhesiveness (or the adhesiveness may remain on the adhesive layer). Even though the cover layer has the curved surface, an adhesion defect or an air bubble may be prevented from occurring. Since the light blocking layer is formed after the curing of the adhesive layer, discoloration of the light blocking layer due to ultraviolet light or heat of a curing process may be prevented.

An effect according to embodiments is not limited by the above-described contents, and more various effects are included in the specification.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a diagram schematically illustrating a display device according to an embodiment;

FIG. 2 is an exploded perspective view schematically illustrating a display device according to an embodiment;

FIG. 3 is a plan view schematically illustrating a display device according to an embodiment;

FIGS. 4 to 6 are cross-sectional views schematically illustrating a display device according to an embodiment;

FIG. 7 is a cross-sectional view schematically illustrating a display panel according to an embodiment;

FIG. 8 is a cross-sectional view schematically illustrating a display panel according to an embodiment;

FIG. 9 is a cross-sectional view schematically illustrating a pixel circuit layer and a display element layer according to an embodiment;

FIG. 10 is a perspective view schematically illustrating a light emitting element according to an embodiment;

FIG. 11 is a cross-sectional view schematically illustrating a light emitting element according to an embodiment; and

FIGS. 12 to 14 are cross-sectional views for each step of a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Although the terms “first,” “second,” and the like may be used herein to describe various elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, such as “a” and “an,” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

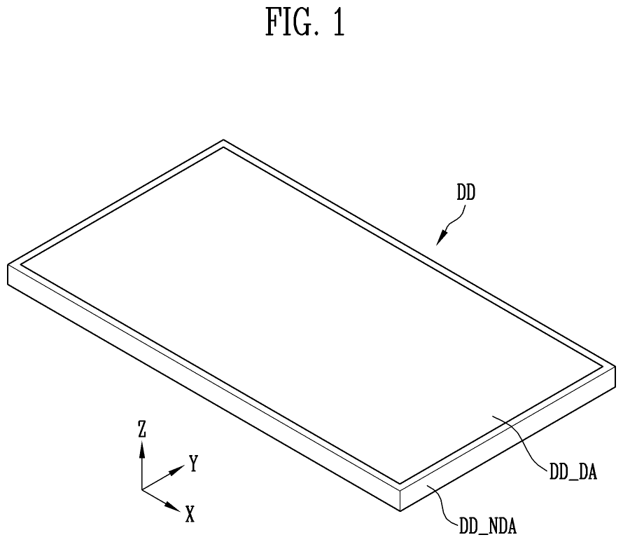

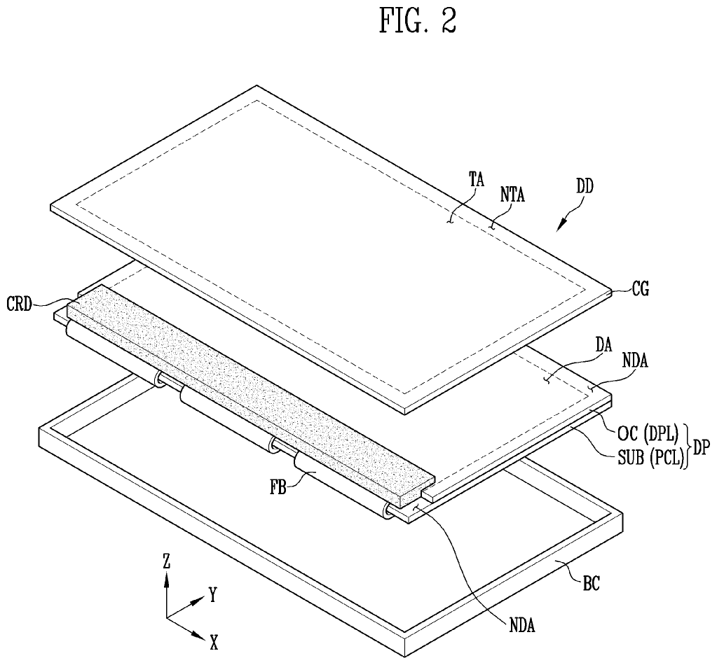

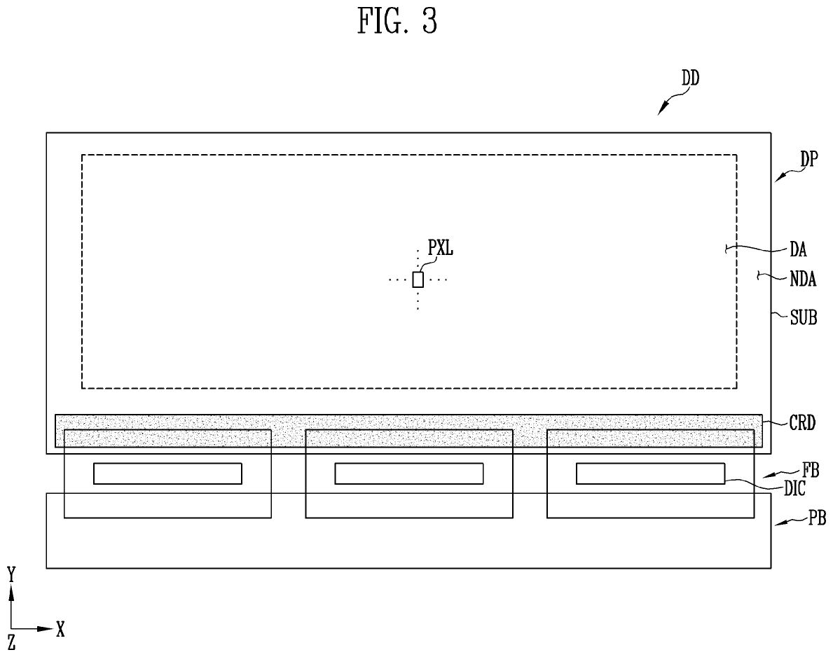

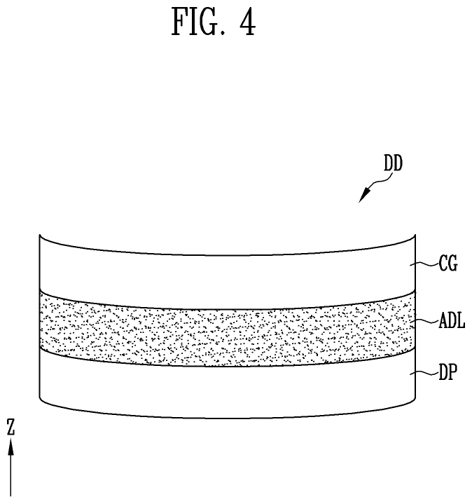

FIG. 1 is a diagram schematically illustrating a display device according to an embodiment. FIG. 2 is an exploded perspective view schematically illustrating a display device according to an embodiment. FIG. 3 is a plan view schematically illustrating a display device according to an embodiment. FIGS. 4 to 6 are cross-sectional views schematically illustrating a display device according to an embodiment. FIG. 7 is a cross-sectional view schematically illustrating a display panel according to an embodiment.

Referring to FIG. 1, the display device DD may display an image through a display surface, for example, a display area DD_DA.

The display device DD may be an electronic device in which a display surface is applied to at least one surface thereof. The electronic device having the display surface may include a smartphone, a television, an automotive display, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable. For example, the disclosure may be applied to the display device DD.

The display device DD may be provided in various shapes. For example, the display device DD may be provided in a rectangular plate shape having two pairs of sides parallel to each other, but the disclosure is not limited thereto. When the display device DD is provided in the rectangular plate shape, a pair of sides of the two pairs of sides may be provided longer than another pair of sides. In the drawing, the display device DD may have an angled corner portion formed of a straight line, but the disclosure is not limited thereto. According to an embodiment, the display device DD provided in the rectangular plate shape may have a round shape at a corner portion where a long side and a short side contact each other.

In an embodiment of the disclosure, for convenience of description, the display device DD may have a rectangular shape having a pair of long sides and a pair of short sides. An extension direction of the long sides may be displayed as a first direction (e.g., an X-axis direction), an extension direction of the short side may be displayed as a second direction (e.g., a Y-axis direction), and a thickness direction of the display device DD (or a substrate SUB) may be displayed as a third direction (e.g., a Z-axis direction).

In an embodiment of the disclosure, at least a portion of the display device DD may have flexibility, and the display device DD may be folded at a portion having flexibility.

The display device DD may include a display area DD_DA displaying an image and a non-display area DD_NDA provided on at least one side of the display area DD_DA. The non-display area DD_NDA may be an area in which an image is not displayed. However, the disclosure is not limited thereto. According to an embodiment, a shape of the display area DD_DA and a shape of the non-display area DD_NDA may be relatively designed. For example, the non-display area DD_NDA may surround the display area DD_DA.

According to an embodiment, the display device DD may include a sensing area and a non-sensing area. The display device DD may display an image through the sensing area and sense a touch input performed on a display surface (or an input surface) or light incident from a front direction. The non-sensing area may surround the sensing area. However, the disclosure is not limited thereto. According to an embodiment, a partial area of the display area DD_DA may correspond to the sensing area. For example, the sensing area may be disposed in the display area DD_DA.

Referring to FIGS. 2 and 3, the display device DD may include a cover layer CG, a display panel DP, and/or a receiving member BC.

The cover layer CG may be disposed on the display panel DP to protect the display panel DP from external impact and transmit an image provided from the display panel DP to a transmission area TA.

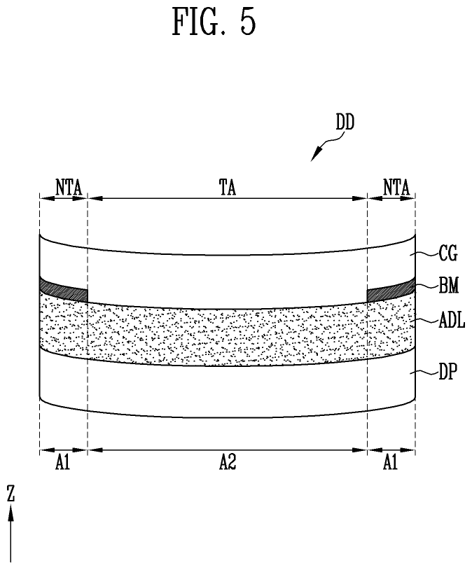

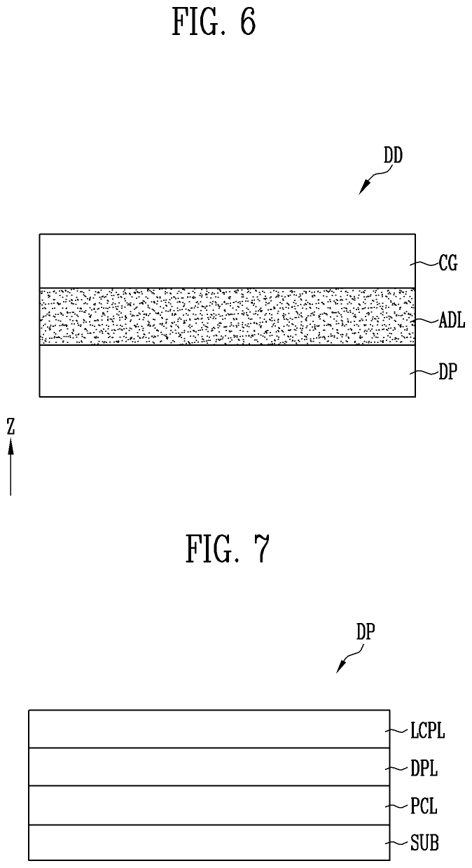

As shown in FIGS. 4 and 5, a surface and/or another surface of the cover layer CG may include a curved surface. The surface and/or another surface of the display panel DP may include a curved surface corresponding to a curved surface of the cover layer CG. However, the disclosure is not limited thereto, and as shown in FIG. 6, the surface and/or the another surface of the cover layer CG may include a flat surface. The surface and/or the another surface of the display panel DP may include a flat surface corresponding to the flat surface of the cover layer CG.

The cover layer CG may include the transmission area TA and a non-transmission area NTA. The transmission area TA may have a shape corresponding to the display area DD_DA of the display device DD. For example, the transmission area TA and the display area DD_DA may have a same shape. For example, the image displayed on the display area DD_DA of the display device DD may be viewed from the outside through the transmission area TA of the cover layer CG.

The non-transmission area NTA may have a shape corresponding to the non-display area DD_NDA of the display device DD. For example, the non-transmission area NTA and the non-display area DD_NDA may have a same shape. The non-transmission area NTA may be an area having light transmittance relatively lower than that of the transmission area TA. However, the disclosure is not limited thereto, and the non-transmission area NTA may be omitted.

The cover layer CG may have a multilayer structure selected from a glass substrate, a plastic film, and a plastic substrate. Such a multilayer structure may be formed through a successive process or an adhesion process using an adhesive layer. The entire or a portion of the cover layer CG may have flexibility.

The display panel DP may be disposed between the cover layer CG and the receiving member BC. The display panel DP may display an image. The display panel DP may emit light independently without a light emitting device. The display panel DP may include an organic light emitting display panel using an organic light emitting diode as a light emitting element, and an ultra-small light emitting diode display panel (e.g., micro-LED or nano-LED) using an ultra-small light emitting diode as a light emitting element, and a quantum dot organic light emitting display panel using a quantum dot and an organic light emitting diode. The display panel DP may include a non-emission display panel, such as a liquid crystal display panel, an electro-phoretic display panel, and an electro-wetting display panel. When the non-emission display panel is used as the display panel DP, the display device DD may include a light emitting device that supplies light to the display panel DP.

The display panel DP may include the substrate SUB and pixels PXL provided on the substrate SUB.

The substrate SUB may be formed of an area having an approximately rectangular shape. However, the number of areas provided on the substrate SUB may be different from the above-described example, and the shape of the substrate SUB may be different from that of the area provided on the substrate SUB.

The substrate SUB may be formed of an insulating material such as glass or resin. The substrate SUB may be formed of a material having flexibility to be bent or folded, and may have a single-layer structure or a multilayer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material configuring the substrate SUB is not limited to the above-described embodiments.

The substrate SUB may include a display area DA and a non-display area NDA. The display area DA may be an area in which the pixels PXL are provided to display an image. The non-display area NDA may be an area in which the pixels PXL are not provided, and an image may not be displayed in the non-display area NDA. For convenience of description, only one pixel PXL is shown in FIG. 3, but multiple pixels PXL may be provided in the display area DA of the substrate SUB.

The display area DA of the substrate SUB (or the display panel DP) may correspond to the display area DD_DA of the display device DD, and the non-display area NDA of the substrate SUB (or the display panel DP) may correspond to the non-display area DD_NDA of the display device DD. The non-display area NDA may correspond to a bezel area of the display device DD.

The non-display area NDA may be provided on at least one side of the display area DA. The non-display area NDA may surround a circumference (or an edge) of the display area DA. A line part and a circuit board FB may be coupled (e.g., electrically connected to each other) in the non-display area NDA. The line part may be electrically connected to the pixels PXL. The circuit board FB may be electrically connected to the line part and drive the pixels PXL.

The line part may electrically connect the circuit board FB and the pixels PXL. The line part may provide a signal to each of the pixels PXL and may be a fan-out line electrically connected to signal lines (e.g., a scan line, a data line, and the like) electrically connected to each of the pixels PXL.

The pixels PXL may be provided in the display area DA of the substrate SUB. Each of the pixels PXL may be a minimum part for displaying an image. Each of the pixels PXL may include a light emitting element emitting white light and/or a color light. Each of the pixels PXL may emit any one color among red, green, and blue, but is not limited thereto, and may emit cyan, magenta, yellow, or the like.

The pixels PXL may be arranged in a matrix form along a row extending in the first direction (e.g., in the X-axis direction) and a column extending in the second direction (e.g., in the Y-axis direction) crossing (or intersecting) the first direction (e.g., in the X-axis direction). However, an arrangement form of the pixels PXL is not limited thereto, and the pixels PXL may be arranged in various forms. The pixels PXL may have a rectangular shape in the drawing, but the disclosure is not limited thereto, and the pixels PXL may be modified into various shapes. When the pixels PXL are provided, the pixels PXL may be provided to have different areas (or sizes). For example, in case that the pixels PXL have different colors of emitted light, the pixels PXL may be provided in different areas (or sizes) or in different shapes for each color.

The circuit board FB may process various signals input from the printed circuit board PB and output the processed various signals to the display panel DP.

The driver DIC may be positioned on the circuit board FB. The driver DIC may be an integrated circuit (IC). The driver DIC may receive driving signals output from the printed circuit board PB and may output a signal, a driving voltage (or a driving power), and the like to be provided to the pixels PXL, based on the received driving signals.

In the above-described embodiment, the driver DIC may be disposed on the circuit board FB, but the disclosure is not limited thereto. According to an embodiment, the driver DIC may be disposed (or mounted) on the substrate SUB of the display panel DP.

The printed circuit board PB may generate overall driving signals and power signals necessary for driving the display panel DP and provide the driving signals and power signals to the display panel DP. The printed circuit board PB may include a pad. The pad may be electrically connected to the pads of the circuit board FB. As a result, the driving signals and the power signals may be transferred from the printed circuit board PB to the driver DIC through the circuit board FB.

The receiving member BC may provide a rear surface of the display device DD and may be coupled to (or may extend from) the cover layer CG to define an internal space of the display device DD. The receiving member BC may include a material having a relatively high rigidity. The receiving member BC may stably protect configurations (or parts) of the display device DD received in the internal space from external impact. The receiving member BC may include a material having high rigidity, but the disclosure is not limited thereto, and the receiving member BC may include a flexible material. Although not shown, the display device DD according to an embodiment of the disclosure may have a characteristic (e.g., a flexible characteristic) in which the display device DD may be folded or bent. Configurations (or parts) included in the display device DD may also have a flexible property.

In an embodiment, the display device DD (or the display panel DP) may further include an upper protective layer CRD (e.g., a protective layer, or a protective part) that at least partially covers the circuit board FB and the display panel DP.

The upper protective layer CRD may cover a side surface of each of the circuit board FB and the display panel DP and prevent corrosion or the like of pads of each of the circuit board FB and the display panel DP. The upper protective layer CRD may cover the side surface of each of the circuit board FB and the display panel DP and block external water, moisture, or the like from flowing into the pixels PXL. The upper protective layer CRD may further firmly couple (or may extend from) the circuit board FB and the display panel DP boned to each other.

In an embodiment, the upper protective layer CRD may be formed of a resin. For example, the upper protective layer CRD may be formed of a thermosetting resin including a thermal polymerization initiator that initiates a curing reaction by heat. According to an embodiment, the upper protective layer CRD may be formed of a light-curable resin including a photopolymerization initiator that is crosslinked and cured by light such as ultraviolet light or infrared light. According to an embodiment, the upper protective layer CRD may include a light blocking material. For example, the upper protective layer CRD may block the circuit board FB. The circuit board FB positioned under the upper protective layer CRD may be prevented from being viewed.

In an embodiment, an adhesive layer ADL may be disposed between the cover layer CG and the display panel DP. The adhesive layer ADL may couple (or may extend between) the cover layer CG and the display panel DP.

A modulus of the adhesive layer ADL at room temperature (e.g., in a range of about 20° C. to about 25° C.) may be in a range of about 10³ Pa to about 10⁶ Pa. For example, the adhesive layer ADL may be in a semi-solid state. A peel strength of the adhesive layer ADL at room temperature may be about 2,000 gf/in or greater. A surface curing rate of the adhesive layer ADL may be about 85% or greater. A deep curing rate of the adhesive layer ADL may be about 85% or greater. An adhesive material layer or an adhesive composition including a photocurable resin or a thermosetting resin may be cured, and the adhesive layer ADL may be formed. For example, an adhesive layer in a liquid state may be applied on the display panel DP and cured to form the adhesive layer ADL in the semi-solid state.

According to an embodiment, the adhesive material layer may include a photocurable acrylic resin, a photoinitiator, a coupling agent, a radical generator, and a solvent.

The photoinitiator is not limited thereto as long as the photoinitiator may cure the acrylic resin with light. For example, the photoinitiator may include at least one of an aromatic diazonium salt, an aromatic sulfonium salt, an aromatic iodine aluminum salt, and an aromatic sulfonium aluminum salt.

The coupling agent may include at least one of a silane-based coupling agent, a titanium-based coupling agent, or a silicone compound.

The radical initiator may be a radical photopolymerization initiator or a thermally decomposable radical polymerization initiator. The radical photopolymerization initiator may be decomposed by an electromagnetic energy ray such as an ultraviolet light and generate a radical. The thermally decomposable radical polymerization initiator may be decomposed by heat and generate a radical.

As the radical photopolymerization initiator, an acetophenone derivative such as 2-hydroxy-2-methylpropiophenone and 1-hydroxycyclohexyl phenyl ketone; an acylphosphine oxide derivative such as bis(2,4,6-trimethylbenzoyl)phenylphosphine oxide; and a type I alpha cleavage initiator such as a benzoin ether derivative such as benzoin methyl ether and benzoin ethyl ether. A type II photoinitiator may also be used, and an example thereof may include a compound such as benzophenone, isopropylthioxanthone, and anthroquinone. As the thermally decomposable radical polymerization initiator, a peroxide such as 1,1,3,3-tetramethylbutylperoxy-2-ethyl-hexanoate, 1,1-bis(t-butylperoxy)cyclohexane, 1,1-bis(t-butylperoxy)cyclo-dodecane, di-t-butylperoxyisophthalate, t-butylperoxybenzoate, dicumylperoxide, t-butylcumylperoxide, 2,5-dimethyl-2,5-di(t-butylperoxy)hexane, 2,5-dimethyl-2,5-di(t-butylperoxy)-3-hexyne, and cumene hydroperoxide may be included. In case that the adhesive material layer includes the above-described radical photopolymerization initiator, a crosslinking reaction between materials may be promoted by inhibiting a reaction with oxygen on a surface of the adhesive material layer in a step of curing the adhesive material layer, thereby increasing the surface curing rate. According to an embodiment, the surface curing rate may be increased using a Thiol-ene reaction, amino acrylate, or the like, but is not limited thereto.

The solvent that may be used for the adhesive material layer may be methyl ethyl ketone (MEK), tetrahydrofuran (THF), toluene, and the like However, the solvent is not limited thereto as long as the solvent may make a crude liquid for forming a film, and a type or a mixture of multiple types of solvents may be used to obtain an excellent film property.

According to an embodiment, the adhesive material layer may include a thermosetting acrylic resin, a heat curing agent, a coupling agent, and a solvent.

The heat curing agent is generally usable as long as the heat curing agent may be used for heat curing the acrylic resin, and is not limited thereto. For example, as the heat curing agent, an amine-based curing agent, an imidazole-based curing agent, an acid anhydride curing agent, a phenol novolak-type curing agent, a polymercaptan curing agent, a tertiary amine compound, an imidazole compound, or the like may be used. However, the disclosure is not limited thereto.

The coupling agent may include at least one of a silane coupling agent, a titanate-based coupling agent, an aluminate-based coupling agent, a silicone compound, and the like. However, the disclosure is not limited thereto. The above-described coupling agents may be used alone or in combination.

According to an embodiment, as shown in FIG. 5, a light blocking layer BM may be disposed between the cover layer CG and the adhesive layer ADL. The light blocking layer BM may overlap the non-transmission area NTA of the cover layer CG in a plan view. The light blocking layer BM may not overlap the transmission area TA of the cover layer CG in a plan view. The light blocking layer BM may prevent light leakage and absorption of external light and reduce color distortion due to external light reflection.

The light blocking layer BM may include a light blocking material such as a black matrix. For example, the light blocking layer BM may be formed of a ceramic, metal, an organic layer, and/or an inorganic layer. The light blocking material may include a material based on at least one of carbon black, titanium black, iron sulfide, or the like, but the light blocking material is not limited thereto.

In case that the adhesive layer ADL is formed with a general optical clear resin (OCR), after the adhesive layer ADL is temporarily cured, the adhesive layer ADL may be mainly cured in a state where the light blocking layer BM and/or the cover layer CG are provided on the adhesive layer ADL, to adhere the adhesive layer ADL and the light blocking layer BM and/or the cover layer. In case that the cover layer CG has a curved surface due to insufficient adhesive strength of the temporarily cured adhesive layer ADL, a bonding defect or an air bubble may partially occur. Even in the main curing step, a first area A1 of the adhesive layer ADL overlapping the light blocking layer BM in a plan view may not be cured. Thus, an adhesion defect may occur, and a discoloration defect of the light blocking layer BM due to ultraviolet light or heat may be formed in the main curing step.

Accordingly, the adhesive layer ADL according to an embodiment may be cured completely before the light blocking layer BM and/or the cover layer CG are bonded, and thus adhesiveness may be manifested. Since the adhesive layer ADL is cured in a state in which the light blocking layer BM is not formed, a surface curing rate and/or a deep curing rate of the first area A1 of the adhesive layer ADL overlapping the light blocking layer BM in a plan view may be equal to a surface curing rate and/or a deep curing rate of a second area A2 of the adhesive layer ADL which does not overlap the light blocking layer BM in a plan view. For example, the adhesive layer ADL may be cured before the light blocking layer BM is formed, and the first area A1 and the second area A2 of the adhesive layer ADL may have a same surface curing rate and/or a same deep curing rate. Accordingly, even though the cover layer CG has a curved surface, the adhesion defect or the air bubble may be prevented from occurring. Since the light blocking layer BM is formed after the adhesive layer ADL is cured, discoloration of the light blocking layer BM due to ultraviolet light or heat in a curing process may be prevented.

Referring to FIG. 7, the display panel DP may include a pixel circuit layer PCL, a display element layer DPL, and a light conversion pattern layer LCPL.

The pixel circuit layer PCL may be provided on the substrate SUB and may include transistors and signal lines electrically connected to the transistors. For example, each of the transistors may have a semiconductor layer, a gate electrode, a first terminal, and a second terminal. The semiconductor layer, the gate electrode, and the first terminal (or the second terminal) may be sequentially stacked one another, and insulating layers may be disposed therebetween. The semiconductor layer may include at least one of amorphous silicon, poly silicon, low temperature poly silicon, and an organic semiconductor. The gate electrode, the first terminal, and the second terminal may include at least one of aluminum (Al), copper (Cu), titanium (Ti), and molybdenum (Mo), but the disclosure is not limited thereto. The pixel circuit layer PCL may include one or more insulating layers.

The display element layer DPL may be disposed on the pixel circuit layer PCL. The display element layer DPL may include a light emitting element emitting light. The light emitting element may be, for example, an organic light emitting diode, but the disclosure is not limited thereto. According to an embodiment, the light emitting element may be an inorganic light emitting element including an inorganic light emitting material. In other embodiments, the light emitting element may be a light emitting element that changes a wavelength of light emitted using a quantum dot and emits light.

The light conversion pattern layer LCPL may be disposed on the display element layer DPL. The light conversion pattern layer LCPL may change a wavelength (or a color) of light emitted from the display element layer DPL by using a quantum dot, and may selectively transmit light of a wavelength (e.g., a specific wavelength or a specific color) by using a color filter. The light conversion pattern layer LCPL may be formed through successive processes on a base surface provided by the display element layer DPL.

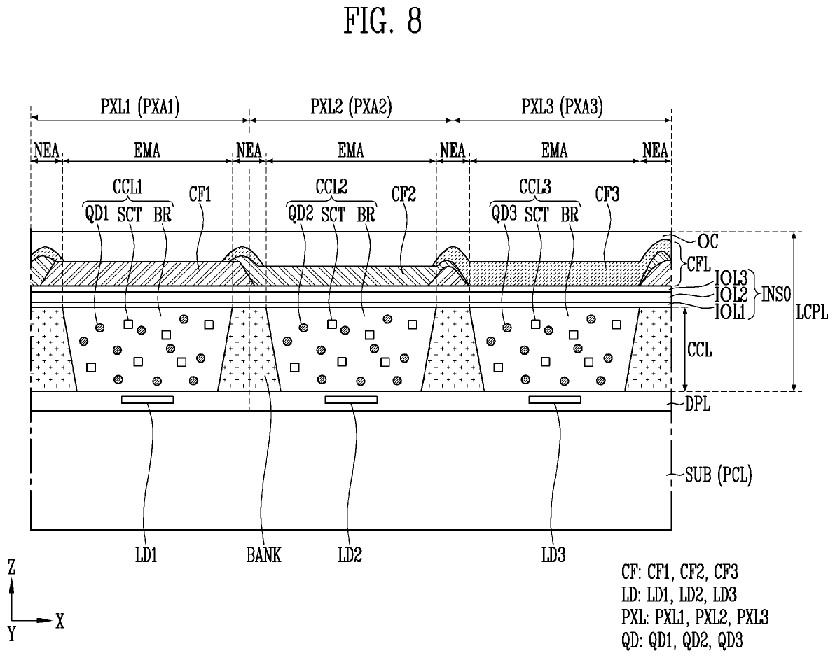

FIG. 8 is a cross-sectional view schematically illustrating a display panel according to an embodiment. In FIG. 8, the display area DA of the display panel DP is briefly shown.

Referring to FIG. 6, a first pixel PXL1, a second pixel PXL2, and a third pixel PXL3 may be disposed on the substrate SUB. The first to third pixels PXL1, PXL2, and PXL3 may configure a pixel part, but the disclosure is not limited thereto.

According to an embodiment, the first to third pixels PXL1, PXL2, and PXL3 may emit light in different colors. For example, the first pixel PXL1 may be a red pixel emitting red light, the second pixel PXL2 may be a green pixel emitting green light, and the third pixel PXL3 may be a blue pixel emitting blue light. However, the color, type, number, and/or the like of pixels configuring the unit pixel are/is not limited thereto. For example, light emitted by each of the pixels may have various colors. According to an embodiment, the first to third pixels PXL1, PXL2, and PXL3 may emit light of a same color. For example, each of the first to third pixels PXL1, PXL2, and PXL3 may be a blue pixel emitting blue light.

In an embodiment of the disclosure, unless otherwise specified, “formed and/or provided on a same layer” may mean formed in a same process, and “formed and/or provided on different layers” may mean formed in different processes.

The pixel circuit layer PCL and the display element layer DPL may be disposed on the substrate SUB. For convenience of description, the pixel circuit layer PCL and the substrate SUB are shown in FIG. 8. However, as described with reference to FIG. 7, the pixel circuit layer PCL may be disposed between the substrate SUB and the display element layer DPL.

The display element layer DPL may include a light emitting element LD provided in each of emission areas EMA. For example, a first light emitting element LD1 may be provided in a first pixel area PXA1, a second light emitting element LD2 may be provided in a second pixel area PXA2, and a third light emitting element LD3 may be provided in a third pixel area PXA3.

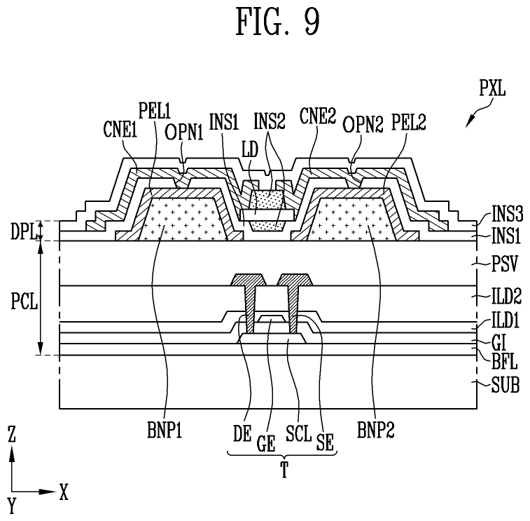

The light emitting element LD may be configured of an organic light emitting diode. In other embodiments, the light emitting element LD may be configured of an inorganic light emitting diode such as a quantum dot light emitting diode. In an embodiment, the light emitting element LD may be an ultra-small light emitting diode (e.g., having a size of a nanometer scale to a micrometer scale) using a material of an inorganic crystal structure. The light emitting elements LD may be electrically connected to each other in parallel and/or in series with adjacent light emitting element LD disposed adjacently in each of the pixels PXL, but the disclosure is not limited thereto. The light emitting element LD may configure a light source of each of the pixels PXL. For example, each of the pixels PXL may include at least one light emitting element LD driven by a signal (e.g., a scan signal, a data signal, or the like) and/or power (e.g., a first driving power, a second driving power, or the like). A detailed description of the pixel circuit layer PCL and the display element layer DPL is described below with reference to FIG. 9.

The light conversion pattern layer LCPL may include a color conversion layer CCL, an insulating layer INS0 (or a refractive index conversion layer), a color filter layer CFL (or a color filter CF), and an overcoat layer OC.

The color conversion layer CCL may include a bank BANK, a first color conversion pattern CCL1, a second color conversion pattern CCL2, and a third color conversion pattern CCL3 (or a first color conversion layer, a second color conversion layer, and a third color conversion layer).

The bank BANK may be disposed on the display element layer DPL. The bank BANK may be positioned in a non-emission area NEA of the first to third pixels PXL1, PXL2, and PXL3 (or a non-emission area NEA between adjacent ones of the first to third pixels PXL1, PXL2, and PXL3). The bank BANK may be formed between the first to third pixels PXL1, PXL2, and PXL3 and surround each of the emission areas EMA. The bank BANK may define each of the emission areas EMA of each of the first to third pixels PXL1, PXL2, and PXL3. The bank BANK may prevent a solution for forming the first to third color conversion patterns CCL1, CCL2, and CCL3 in the emission area EMA from flowing into adjacent emission area EMA of an adjacent pixel. For example, the bank BANK may function as a dam structure that controls an amount (e.g., a predetermined or selectable amount) of solution to be supplied to each of the emission areas EMA.

An opening for exposing the display element layer DPL may be formed in the bank BANK and correspond to the emission area EMA. The first to third color conversion patterns CCL1, CCL2, and CCL3 may be disposed in each of openings of the bank BANK.

The first to third color conversion patterns CCL1, CCL2, and CCL3 may include a base resin BR, color conversion particles QD, and light scattering particles SCT. The base resin BR may have high light transmittance and an excellent dispersion characteristic for the color conversion particles QD. For example, the base resin BR may include at least one organic material of an epoxy-based resin, an acryl-based resin, a cardo-based resin, and an imide-based resin.

The color conversion particles QD may convert light of a color emitted from the light emitting element LD disposed in a pixel into light of a color (e.g., a specific or selectable color) corresponding to the pixel. For example, when the first pixel PXL1 is a red pixel, the first color conversion layer CCL1 may include first color conversion particles QD1 of a red quantum dot converting light emitted from the first light emitting element LD1 into red light. For example, when the second pixel PXL2 is a green pixel, the second color conversion layer CCL2 may include second color conversion particles QD2 of a green quantum dot converting light emitted from the second light emitting element LD2 into green light. For example, when the third pixel PXL3 is a blue pixel, the third color conversion layer CCL3 may include third color conversion particles QD3 of a blue quantum dot converting light emitted from the third light emitting device LD3 into blue light. In other embodiments, when the third light emitting element LD3 emits blue light, the third color conversion layer CCL3 may not include the third color conversion particles QD3.

The light scattering particles SCT may have a refractive index different from that of the base resin BR and form an optical interface with the base resin BR. The light scattering particles SCT may be metal oxide particles or organic particles. According to an embodiment, the light scattering particles SCT may be omitted.

The insulating layer INS0 may be disposed on the color conversion layer CCL. The insulating layer INS0 may be disposed (e.g., entirely disposed) on the substrate SUB and cover the color conversion layer CCL (e.g., the bank BANK and the first to third color conversion patterns CCL1, CCL2, and CCL3).

The insulating layer INS0 may include at least three insulating layers, and may recycle light (e.g., light proceeding in an oblique direction) emitted from the color conversion layer CCL using a refractive index difference (or total reflection due to the refractive index difference) between the three insulating layers. For example, the light totally reflected by the insulating layer INS0 may be reflected again in the third direction (e.g., in the Z-axis direction) by the display element layer DPL (or an electrode included in the display element layer DPL and having a specific or selectable reflectance), or may be scattered in the third direction (e.g., in the Z-axis direction) by the color conversion layer CCL (e.g., the light scattering particle SCT). Therefore, efficiency (e.g., external quantum efficiency or light output efficiency) of light finally emitted from the pixel PXL through the insulating layer INS0 or an emission luminance of the pixel PXL may be improved.

In other embodiments, the insulating layer INS0 may include a first inorganic layer IOL1 (or a first dense film), a second inorganic layer IOL2 (or a low refractive film), and a third inorganic layer IOL3 (or a second dense film) sequentially stacked on the color conversion layer CCL.

The first inorganic layer IOL1 may be disposed on the color conversion layer CCL, and may prevent moisture (or a solution used in a subsequent process) from penetrating the color conversion layer CCL thereunder. The second inorganic layer IOL2 may be disposed on the first inorganic layer IOL1, and may totally reflect the light (e.g., the light proceeding in an oblique direction) emitted from the color conversion layer CCL using a refractive index difference with the first inorganic layer TOLL For example, the light emitted from the color conversion layer CCL may be totally reflected from an interface between the first inorganic layer IOL1 and the second inorganic layer IOL2. The third inorganic layer IOL3 may be disposed on the second inorganic layer IOL2 and may improve adhesion force between the second inorganic layer IOL2 and the color filter layer CFL thereon.

The color filter layer CFL may be disposed on the insulating layer INS0. The color filter layer CFL may include a color filter material that selectively transmits light of a color (e.g., a specific or selectable color) converted by the color conversion layer CCL. The color filter layer CFL may include a red color filter, a green color filter, and a blue color filter. For example, when the first pixel PXL1 is the red pixel, a first color filter CF1 that transmits red light may be disposed on the first pixel PXL1. When the second pixel PXL2 is the green pixel, a second color filter CF2 that transmits green light may be disposed on the second pixel PXL2. When the third pixel PXL3 is the blue pixel, a third color filter CF3 that transmits blue light may be disposed on the third pixel PXL3.

The overcoat layer OC may be disposed on the color filter layer CFL. The overcoat layer OC may be disposed (e.g., entirely disposed) on the substrate SUB and cover a lower configuration (or a lower part). The overcoat layer OC may encapsulate the display area DA of the display panel DP.

FIG. 9 is a cross-sectional view schematically illustrating a pixel circuit layer and a display element layer according to an embodiment. In a pixel PXL of FIG. 9, each electrode has a single layer and each insulating layer has a single layer. However, the disclosure is not limited thereto.

Referring to FIG. 9, each of the pixels PXL may include the pixel circuit layer PCL and the display element layer DPL disposed on the substrate SUB.

The pixel circuit layer PCL may include a buffer layer BFL, a transistor T, and a protective layer PSV.

The buffer layer BFL may be provided and/or formed on the substrate SUB and may prevent an impurity from diffusing into the transistor T. The buffer layer BFL may be an inorganic insulating layer including an inorganic material. The buffer layer BFL may include at least one of silicon nitride (SiNₓ), silicon oxide (SiOₓ), silicon oxynitride (SiOₓ N_{y}), and aluminum oxide (AlOₓ). The buffer layer BFL may be provided as a single layer. In other embodiments, the buffer layer BFL may be provided as a multilayer of at least a double layer. When the buffer layer BFL is provided as the multilayer, each layer may be formed of a same material or different materials. The buffer layer BFL may be omitted according to a material, a process condition, and the like of the substrate SUB.

The transistor T may be a driving transistor that controls a driving current provided to the light emitting element LD. However, the disclosure is not limited thereto, and the transistor T may be a switching transistor that transfers a signal to the driving transistor or performs another function in addition to the driving transistor.

The transistor T may include a semiconductor pattern SCL, a gate electrode GE, a first terminal SE, and a second terminal DE. The first terminal SE may be one of a source electrode and a drain electrode, and the second terminal DE may be another of the source electrode and the drain electrode. For example, when the first terminal SE is a source electrode, the second terminal DE may be a drain electrode.

The semiconductor pattern SCL may be provided and/or formed on the buffer layer BFL. The semiconductor pattern SCL may include a first contact region contacting the first terminal SE and a second contact region contacting the second terminal DE. A region of the semiconductor pattern SCL between the first contact region and the second contact region may be a channel region. The channel region of the semiconductor pattern SCL may overlap the gate electrode GE of the corresponding transistor T in a plan view. The semiconductor pattern SCL may be a semiconductor pattern including at least one of amorphous silicon, poly silicon, low temperature poly silicon, an oxide semiconductor, and an organic semiconductor. However, the disclosure is not limited thereto. For example, the channel region a semiconductor part not doped with an impurity, and may be an intrinsic semiconductor. The first contact region and the second contact region of the semiconductor pattern SCL may be semiconductor parts doped with an impurity.

The gate electrode GE may be provided and/or formed on a gate insulating layer GI and correspond to the channel region of the semiconductor pattern SCL. The gate electrode GE may be provided on the gate insulating layer GI and may overlap the channel region of the semiconductor pattern SCL in a plan view. The gate electrode GE may be formed in a single layer of a material selected from a group consisting of copper (Cu), molybdenum (Mo), tungsten (W), aluminum neodymium (AlNd), titanium (Ti), aluminum (Al), silver (Ag), and an alloy thereof alone or a mixture thereof, or may be formed in a double layer or multilayer structure of a molybdenum (Mo), titanium (Ti), copper (Cu), aluminum (Al) or silver (Ag), which is a low-resistance material, to reduce a line resistance.

The gate insulating layer GI may be an inorganic insulating layer including an inorganic material. For example, the gate insulating layer GI may include at least one of a metal oxide such as silicon nitride (SiNₓ), silicon oxide (SiOₓ), silicon oxynitride (SiOₓN_{y}), and aluminum oxide (AlOₓ). However, the material of the gate insulating layer GI is not limited to the above-described embodiments, and various materials providing electrical insulation to the gate insulating layer GI may be applied to the gate insulating layer GI according to an embodiment. For example, the gate insulating layer GI may be formed of an organic insulating layer including an organic material. The gate insulating layer GI may be provided as a single layer, but may also be provided as a multilayer of at least a double layer. Each of the first terminal SE and the second terminal DE may be provided and/or formed on a second interlayer insulating layer ILD2, and may be in contact with the first contact region and the second contact region of the semiconductor pattern SCL through a contact hole sequentially passing through the gate insulating layer GI, a first interlayer insulating layer ILD1, and the second interlayer insulating layer ILD2. For example, the first terminal SE may be in contact with the first contact region of the semiconductor pattern SCL, and the second terminal DE may be in contact with the second contact region of the semiconductor pattern SCL. The first terminal SE, the second terminal DE, and the gate electrode GE may include a same material. For example, each of the first and second terminals SE and DE may include one or more materials selected from the material that may be used to form the gate electrode GE, e.g., as described herein.

The first interlayer insulating layer ILD1 and the gate insulating layer GI may include a same material. For example, the first interlayer insulating layer ILD1 may include one or more materials selected from the material that may be used to form the gate insulating layer GI, e.g., as described herein.

The second interlayer insulating layer ILD2 may be provided and/or formed on the first interlayer insulating layer ILD1. The second interlayer insulating layer ILD2 may be an inorganic insulating layer including an inorganic material or an organic insulating layer including an organic material. According to an embodiment, the first interlayer insulating layer ILD1 and the second interlayer insulating layer ILD2 may include a same material, but the disclosure is not limited thereto. The second interlayer insulating layer ILD2 may be provided as a single layer or may be provided as a multilayer of at least a double layer. According to an embodiment, the second interlayer insulating layer ILD2 may be omitted.

In the above-described embodiment, the first and second terminals SE and DE of the transistor T may be separate electrodes electrically connected to the semiconductor pattern SCL through the contact holes sequentially passing through the gate insulating layer GI and the first and second interlayer insulating layers ILD1 and ILD2, but the disclosure is not limited thereto. According to an embodiment, the first terminal SE of the transistor T may be the first contact region adjacent to the channel region of the semiconductor pattern SCL, and the second terminal DE of the transistor T may be the second contact region adjacent to the channel region of the semiconductor pattern SCL. The second terminal DE of the transistor T may be electrically connected to the light emitting element LD of the pixel PXL through a separate connection part such as a bridge electrode.

The transistor T may be configured of a low temperature polysilicon thin film transistor (LTPS TFT), but the disclosure is not limited thereto. According to an embodiment, the transistors T may be configured of an oxide semiconductor thin film transistor. Although the transistor T is a thin film transistor of a top gate structure in the above-described embodiment, the disclosure is not limited thereto, and the transistor T may have various structures. For example, the transistor T may be a thin film transistor having a bottom gate structure.

The pixel circuit layer PCL may further include a storage capacitor storing a voltage applied between a gate electrode (e.g., the gate electrode G) and the first terminal SE (or the source electrode) of the transistor T, a driving voltage line providing a driving voltage to the transistor T (or the pixel PXL), and the like.

The protective layer PSV may be provided and/or formed on the transistor T.

The protective layer PSV may be provided in a form including an organic insulating layer, an inorganic insulating layer, or an organic insulating layer disposed on an inorganic insulating layer. The inorganic insulating layer of the protective layer PSV may include, for example, at least one of a metal oxide such as silicon oxide (SiOₓ), silicon nitride (SiNₓ), silicon oxynitride (SiOₓN_{y}), and aluminum oxide (AlOₓ). The organic insulating layer of the protective layer PSV may include, for example, at least one of acrylic resin (polyacrylates resin), epoxy resin, phenolic resin, polyamides resin, polyimide resin, unsaturated polyesters resin, poly-phenylen ethers resin, poly-phenylene sulfides resin, and benzocyclobutene resin.

The display element layer DPL may be provided on the protective layer PSV. The display element layer DPL may include a first bank pattern BNP1, a second bank pattern BNP2, a first pixel electrode PEL1, a second pixel electrode PEL2, the light emitting element LD, a first connection electrode CNE1, and a second connection electrode CNE2. The display element layer DPL may include a first insulating layer INS1, a second insulating layer INS2, and a third insulating layer INS3.

The first and second bank patterns BNP1 and BNP2 may be positioned in the emission area EMA (e.g., refer to FIG. 6) and may be spaced apart from each other. The first and second bank patterns BNP1 and BNP2 may support the first and second pixel electrodes PEL1 and PEL2 and change a surface profile (or a shape) of the first and second pixel electrodes PEL1 and PEL2 in the third direction (e.g., in the Z-axis direction), respectively. Thus, light emitted from the light emitting elements LD may be guided in an image display direction (e.g., a front surface direction) of the display device DD. For example, the first and second bank patterns BNP1 and BNP2 may change the surface profile (or the shape) of each of the first and second pixel electrodes PEL1 and PEL2 in the third direction (e.g., the Z-axis direction).

The first and second bank patterns BNP1 and BNP2 may be provided and/or formed between the protective layer PSV and corresponding electrodes (e.g., the first and second pixel electrodes PEL1 and PEL2) in the emission area EMA of a corresponding pixel PXL. For example, the first bank pattern BNK1 may be provided and/or formed between the protective layer PSV and the first pixel electrode PEL1, and the second bank pattern BNK2 may be provided and/or formed between the protective layer PSV and the second pixel electrode PEL2.

The first and second bank patterns BNP1 and BNP2 may be an inorganic insulating layer including an inorganic material or an organic insulating layer including an organic material. According to an embodiment, the first and second bank patterns BNP1 and BNP2 may include a single organic insulating layer and/or a single inorganic insulating layer, but the disclosure is not limited thereto. According to an embodiment, the first and second bank patterns BNP1 and BNP2 may include a multilayer in which at least one organic insulating layer and at least one inorganic insulating layer are stacked one another. However, the material of the first and second bank patterns BNP1 and BNP2 is not limited to the above-described embodiments.

The first and second bank patterns BNP1 and BNP2 may have a trapezoidal shape of cross-section in which a width becomes narrower from a surface (e.g., an upper surface) of the protective layer PSV toward an upper portion in the third direction (e.g., in the Z-axis direction), but the disclosure is not limited thereto. According to an embodiment, the first and second bank patterns BNP1 and BNP2 may include a curved surface having a cross-section of a semi-elliptical shape, a semi-circular shape (or a hemispherical shape), or the like. A cross-sectional shape of the first and second bank patterns BNP1 and BNP2 is not limited to the above-described embodiments, and the first and second bank patterns BNP1 and BNP2 may have various cross-sectional shapes to improve efficiency of the light emitted from each of the light emitting elements LD. The first and second bank patterns BNP1 and BNP2 adjacent in the first direction (e.g., in the X-axis direction) may be disposed on a same surface of the protective layer PSV, and may have a same height (or thickness) in the third direction (e.g., in the Z-axis direction).

In the above-described embodiment, the first and second bank patterns BNP1 and BNP2 may be provided and/or formed on the protective layer PSV, and the first and second bank patterns BNP1 and BNP2 and the protective layer PSV may be formed by different processes, but the disclosure is not limited thereto. According to an embodiment, the first and second bank patterns BNP1 and BNP2 and the protective layer PSV may be formed through a same process. The first and second bank patterns BNP1 and BNP2 may be regions (or parts) of the protective layer PSV.

The first and second pixel electrodes PEL1 and PEL2 may be provided and/or formed on the first and second bank patterns BNP1 and BNP2 and overlap the first and second bank patterns BNP1 and BNP2 in a plan view, respectively.

Each of the first and second pixel electrodes PEL1 and PEL2 may be formed of a reflective material, and the light emitted from the light emitting element LD may proceed in the image display direction of the display device DD. Each of the first and second pixel electrodes PEL1 and PEL2 may be formed of a reflective conductive material. The reflective conductive material of the first and second pixel electrodes PEL1 and PEL2 may include an opaque metal advantageous for reflecting the light emitted from the light emitting element LD in the image display direction of the display device DD. The opaque metal of the first and second pixel electrodes PEL1 and PEL2 may include, for example, a metal such as silver (Ag), magnesium (Mg), aluminum (Al), platinum (Pt), palladium (Pd), gold (Au), nickel (Ni), neodymium (Nd), iridium (Jr), chromium (Cr), titanium (Ti), and an alloy thereof. According to an embodiment, each of the first and second pixel electrodes PEL1 and PEL2 may include a transparent conductive material. The transparent conductive material of the first and second pixel electrodes PEL1 and PEL2 may include a conductive oxide or a conductive polymer. For example, the conductive oxide of the first and second pixel electrodes PEL1 and PEL2 may include at least one of indium tin oxide (ITO), indium zinc oxide (IZO), indium gallium zinc oxide (IGZO), and indium tin zinc oxide (ITZO). The conductive polymer of the first and second pixel electrodes PEL1 and PEL2 may include poly(3,4-ethylenedioxythiophene) (PEDOT), and the like.

In case that each of the first and second pixel electrodes PEL1 and PEL2 includes a transparent conductive material, a separate conductive layer formed of an opaque metal for reflecting the light emitted from the light emitting element LD may be disposed in the image display direction of the display device DD. However, the material of each of the first and second pixel electrodes PEL1 and PEL2 is not limited to the above-described materials.

Each of the first and second pixel electrodes PEL1 and PEL2 may be provided and/or formed as a single layer, but the disclosure is not limited thereto. According to an embodiment, each of the first and second pixel electrodes PEL1 and PEL2 may be provided and/or formed as a multilayer in which at least two or more materials among metals, alloys, conductive oxides, and conductive polymers are stacked one another. Each of the first and second pixel electrodes PEL1 and PEL2 may be formed of a multilayer of a double or more layers to minimize distortion due to a signal delay when transferring a signal (or a voltage) to ends (e.g., both ends) of each of the light emitting elements LD. For example, each of the first and second pixel electrodes PEL1 and PEL2 may be formed in a multilayer in which indium tin oxide (ITO)/silver (Ag)/indium tin oxide (ITO) are sequentially stacked.

According to an embodiment, the first pixel electrode PEL1 may be electrically connected to the transistor T through a first contact hole passing through the protective layer PSV, and the second pixel electrode PEL2 may be electrically connected to a driving voltage line of the pixel circuit layer PCL through a second contact hole passing through the protective layer PSV.

Each of the first pixel electrode PEL1 and the second pixel electrode PEL2 may be used as alignment electrodes (or alignment lines) that receive an alignment signal (or an alignment voltage) from a corresponding partial configuration (or a corresponding part) of the pixel circuit layer PCL to align the light emitting elements LD between the first and second pixel electrodes PEL1 and PEL2. For example, the first pixel electrode PEL1 may receive a first alignment signal (or a first alignment voltage) from a partial configuration (or a part) of the pixel circuit layer PCL and may be used as a first alignment electrode (or a first alignment line). The second pixel electrode PEL2 may receive a second alignment signal (or a second alignment voltage) from another configuration (or another part) of the pixel circuit layer PCL and may be used as a second alignment electrode (or a second alignment line).

After the light emitting element LD is aligned in the pixel PXL, a portion of the first pixel electrode PEL1 positioned between adjacent pixels PXL may be removed. Thus, the pixel PXL may be driven individually (or independently).

After the light emitting element LD is aligned, the first pixel electrode PEL1 and the second pixel electrode PEL2 may be used as driving electrodes for driving the light emitting elements LD.

At least two to tens of light emitting elements LD may be arranged and/or provided in each of the emission areas EMA, but the number of light emitting elements LD arranged and/or provided in the emission area EMA is not limited thereto. According to an embodiment, light emitting elements LD of various numbers may be arranged and/or provided in each of the emission areas EMA.

Each of the light emitting elements LD may emit any one of color light and/or white light. In an embodiment, each of the light emitting elements LD may emit blue light of a short wavelength band, but the disclosure is not limited thereto.

The first insulating layer INS1 may be provided and/or formed on the first and second pixel electrodes PEL1 and PEL2.

The first insulating layer INS1 may include an inorganic insulating layer formed of an inorganic material or an organic insulating layer formed of an organic material. The first insulating layer INS1 may be formed of the inorganic insulating layer and protect the light emitting element LD from the pixel circuit layer PCL of the pixel PXL. For example, the first insulating layer INS1 may include at least one of a metal oxide such as silicon nitride (SiNₓ), silicon oxide (SiOₓ), silicon oxynitride (SiOₓN_{y}), and aluminum oxide (AlOₓ), but the disclosure is not limited thereto. According to an embodiment, the first insulating layer INS1 may be formed of an organic insulating layer and planarize a surface for supporting the light emitting elements LD. For example, in case that the first insulating layer INS1 is formed of the organic insulating layer, the first insulating layer INS1 may have the planarized surface support the light emitting elements LD on the planarized surface.

The first insulating layer INS1 may include a first opening OPN1 exposing a region of the first pixel electrode PEL1 and a second opening OPN2 exposing a region of the second pixel electrode PEL2. The first insulating layer INS1 may cover remaining regions except for regions of the first and second pixel electrodes PEL1 and PEL2 (e.g., the regions corresponding to the first and second openings OPN1 and OPN2). The light emitting elements LD may be disposed (or aligned) on the first insulating layer INS1 between the first pixel electrode PEL1 and the second pixel electrode PEL2.

The second insulating layer INS2 (or a second insulating pattern) may be provided and/or formed on each of the light emitting elements LD. The second insulating layer INS2 may be provided and/or formed on the light emitting element LD and partially cover an outer circumferential surface (or a surface) of the light emitting element LD. An active layer of the light emitting element LD may not be in contact with an external conductive material by the second insulating layer INS2. The second insulating layer INS2 may cover only a portion of the outer peripheral surface (or the surface) of the light emitting element LD and expose the both ends of the light emitting element LD to the outside.

The second insulating layer INS2 may be configured of a single layer or a multilayer, and may include an inorganic insulating layer including at least one inorganic material or an organic insulating layer including at least one organic material. According to an embodiment, the second insulating layer INS2 may be formed of an inorganic insulating layer including an inorganic material or an organic insulating layer including an organic material. After the light emitting element LD is aligned in the pixel PXL, the second insulating layer INS2 may be formed on the light emitting element LD and prevent the light emitting element LD from being separated from an aligned position.

The first connection electrode CNE1 may be provided on the first pixel electrode PEL1 to be in contact with or to be electrically connected to the first pixel electrode PEL1 through the first opening OPN1 of the first insulating layer INS1. According to an embodiment, when a capping layer (not shown) is disposed on the first pixel electrode PEL1, the first connection electrode CNE1 may be disposed on the capping layer and may be electrically connected to the first pixel electrode PEL1 through the capping layer. The above-described capping layer may protect the first pixel electrode PEL1 from a defect or the like generated during a manufacturing process of the display device DD, and may further strengthen adhesion force between the first pixel electrode PEL1 and the pixel circuit layer PCL positioned thereunder. The capping layer may include a transparent conductive material (or substance) such as indium zinc oxide (IZO).

The first connection electrode CNE1 may be provided and/or formed on an end of the light emitting element LD. The first connection electrode CNE1 may be electrically connected to the end of the light emitting element LD. Accordingly, the first pixel electrode PEL1 and the end of the light emitting element LD may be electrically connected to each other through the first connection electrode CNE1.

Similarly to the first connection electrode CNE1, the second connection electrode CNE2 may be provided on the second pixel electrode PEL2 to be in contact with or to be connected to the second pixel electrode PEL2 through the second opening OPN2 of the first insulating layer INS1. According to an embodiment, when a capping layer is disposed on the second pixel electrode PEL2, the second connection electrode CNE2 may be disposed on the capping layer and may be electrically connected to the second pixel electrode PEL2 through the capping layer. The second connection electrode CNE2 may be provided and/or formed on another end of the light emitting element LD. The second connection electrode CNE2 may be electrically connected to the another end of the light emitting element LD. Accordingly, the second pixel electrode PEL2 and the another end of the light emitting element LD may be electrically connected to each other through the second connection electrode CNE2.

The first and second connection electrodes CNE1 and CNE2 may be formed of various transparent conductive materials, and light emitted from the light emitting element LD and reflected by the first and second pixel electrodes PEL1 and PEL2 may proceed in the image display direction of the display device DD without loss. For example, the first and second connection electrodes CNE1 and CNE2 may include at least one of various transparent conductive materials (or substances) including indium tin oxide (ITO), indium zinc oxide (IZO), indium gallium zinc oxide (IGZO), indium tin zinc oxide (ITZO), and the like, and may be configured to be substantially transparent or translucent to satisfy a light transmittance (or transmittance). However, the material of the first and second connection electrodes CNE1 and CNE2 is not limited to the above-described embodiment. According to an embodiment, the first and second connection electrodes CNE1 and CNE2 may be formed of various opaque conductive materials (or substances). The first and second connection electrodes CNE1 and CNE2 may be formed as a single layer or a multilayer.

A shape of the first and second connection electrodes CNE1 and CNE2 may not be limited to a shape (e.g., a specific or selectable shape), and the first and second connection electrodes CNE1 and CNE2 may have various shapes to be electrically and stably connected to the light emitting element LD. The first and second connection electrodes CNE1 and CNE2 may have various shapes to satisfy an electrical connection relationship with electrodes disposed thereunder.

The first and second connection electrodes CNE1 and CNE2 may be disposed to be spaced apart from each other in the first direction (e.g., in the X-axis direction). For example, the first connection electrode CNE1 and the second connection electrode CNE2 may be disposed to be spaced apart from each other with a distance (e.g., a predetermined or selectable distance) therebetween on the second insulating layer INS2. The first connection electrode CNE1 and the second connection electrode CNE2 may be provided on a same layer and may be formed through a same process. However, the disclosure is not limited thereto, and according to an embodiment, the first and second connection electrodes CNE1 and CNE2 may be provided on different layers and may be formed through different processes.

The third insulating layer INS3 may be provided and/or formed on the first and second connection electrodes CNE1 and CNE2. The third insulating layer INS3 may be an inorganic insulating layer including an inorganic material or an organic insulating layer including an organic material. For example, the third insulating layer INS3 may have a structure in which at least one inorganic insulating layer and/or at least one organic insulating layer are alternately stacked each other. The third insulating layer INS3 may cover (e.g., entirely cover) the display element layer DPL and prevent water, moisture, or the like from flowing into the display element layer DPL including the light emitting elements LD from the outside.

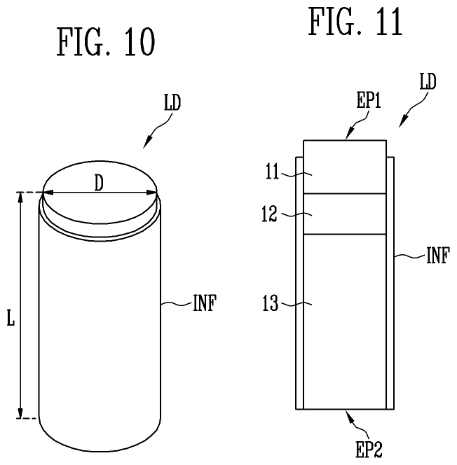

FIG. 10 is a perspective view schematically illustrating a light emitting element according to an embodiment. FIG. 11 is a cross-sectional view schematically illustrating a light emitting element according to an embodiment. FIGS. 10 and 11 show a column shape of light emitting element LD, a type and/or a shape of the light emitting element LD applicable to the above-described display device DD are/is not limited thereto.

Referring to FIGS. 10 and 11, the light emitting element LD may include a first semiconductor layer 11, an active layer 12, and/or a second semiconductor layer 13.

The light emitting element LD may be formed in a column shape extending in a direction. The light emitting element LD may have a first end EP1 and a second end EP2. One of the first and second semiconductor layers 11 and 13 may be disposed at the first end EP1 of the light emitting element LD. Another of the first and second semiconductor layers 11 and 13 may be disposed at the second end EP2 of the light emitting element LD. For example, the first semiconductor layer 11 may be disposed at the first end EP1 of the light emitting element LD, and the second semiconductor layer 13 may be disposed at the second end EP2 of the light emitting element LD.

According to an embodiment, the light emitting element LD may be a light emitting element manufactured in a column shape through an etching method or the like. In the specification, the column shape of the light emitting element LD may include a rod-like shape or a bar-like shape of which an aspect ratio is greater than 1. For example, the light emitting element LD may have a circular column or a polygonal column. However, the shape of the cross-section thereof is not limited thereto.

The light emitting element LD may have a size as small as a nanometer scale to a micrometer scale. For example, the light emitting element LD may have a diameter D (or width) and/or a length L of a nanometer scale to micrometer scale range. However, a size of the light emitting element LD is not limited thereto, and the size of the light emitting element LD may be variously changed according to a design condition of various devices (e.g., a display device or the like) using a light emitting device using the light emitting element LD as a light source, for example, a display device or the like.

The first semiconductor layer 11 may be a semiconductor layer of a first conductivity type. For example, the first semiconductor layer 11 may include a p-type semiconductor layer. For example, the first semiconductor layer 11 may include at least one semiconductor material among InAlGaN, GaN, AlGaN, InGaN, and AlN, and may include a p-type semiconductor layer doped with a first conductivity type dopant such as Mg. However, a material configuring the first semiconductor layer 11 is not limited thereto, and various other materials may configure the first semiconductor layer 11.

The active layer 12 may be disposed between the first semiconductor layer 11 and the second semiconductor layer 13. The active layer 12 may include any one of a single well structure, a multi well structure, a single quantum well structure, a multi quantum well (MQW) structure, a quantum dot structure, or a quantum wire structure, but the disclosure is not limited thereto. The active layer 12 may include at least one of GaN, InGaN, InAlGaN, AlGaN, and AlN, and various other materials may configure the active layer 12.

In case that a voltage equal to or greater than a threshold voltage is applied to ends (e.g., both ends) of the light emitting element LD, an electron-hole pair may be combined in the active layer 12 and the light emitting element LD may emit light. Emission of the light emitting element LD may be controlled using such a principle, and the light emitting element LD may be used as a light source of various light emitting devices including the pixel PXL of the display device DD.

The second semiconductor layer 13 may be disposed on the active layer 12 and may include a semiconductor layer of a type different from that of the first semiconductor layer 11. The second semiconductor layer 13 may include an n-type semiconductor layer. For example, the second semiconductor layer 13 may include at least one semiconductor material of InAlGaN, GaN, AlGaN, InGaN, and AlN, and may include an n-type semiconductor layer doped with a second conductivity type dopant such as Si, Ge, and Sn. However, a material configuring the second semiconductor layer 13 is not limited thereto, and various other materials may configure the second semiconductor layer 13.

According to an embodiment, an electrode layer may be further disposed on the first end EP1 and/or the second end EP2 of the light emitting element LD3. The electrode layer may include a transparent metal or a transparent metal oxide. For example, the electrode layer may include at least one of indium tin oxide (ITO), indium zinc oxide (IZO), and zinc tin oxide (ZTO), but is not limited thereto. As described above, when the electrode layer is formed of the transparent metal or the transparent metal oxide, light generated in the active layer 12 of the light emitting element LD may pass through the electrode layer and may be emitted to an outside of the light emitting element LD.

An insulating film INF may be provided on a surface of the light emitting element LD. The insulating film INF may be disposed (e.g., directly disposed) on a surface (e.g., side surfaces) of the first semiconductor layer 11, the active layer 12, and/or the second semiconductor layer 13. The insulating film INF may expose the first and second ends EP1 and EP2 of the light emitting element LD having different polarities. According to an embodiment, the insulating film INF may expose a side portion (or a part of a side portion) of the first semiconductor layer 11 and/or the second semiconductor layer 13 adjacent to the first and second ends EP1 and EP2 of the light emitting element LD.

The insulating film INF may prevent an electrical short that may occur when the active layer 12 comes into contact with a conductive material except for the first and second semiconductor layers 11 and 13. For example, the insulating film INF may prevent a short circuit between the active layer 12 and other conductive materials except for the first semiconductor layer 11 or the second semiconductor 13. The insulating film INF may minimize a surface defect of the light emitting elements LD. Thus, lifespan and emission efficiency of the light emitting elements LD may be improved.

The insulating film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). For example, the insulating film INF may be configured as double layers, and each layer configuring the double layers of the insulating film INF may include different materials. For example, the insulating film INF may be configured as double layers configured of aluminum oxide (AlOₓ) and silicon oxide (SiOₓ), but is not limited thereto. According to an embodiment, the insulating film INF may be omitted.

Detailed description of a method of manufacturing the display device according to the above-described embodiment is provided below.

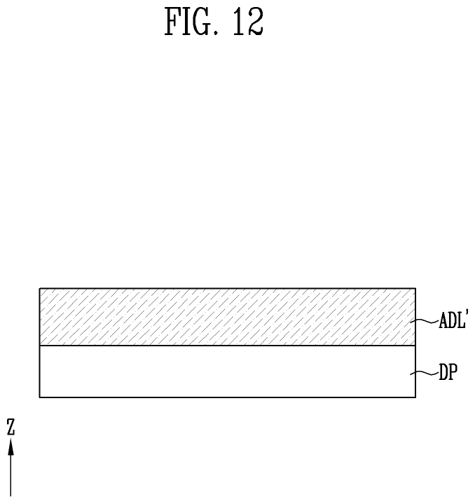

FIGS. 12 to 14 are schematic cross-sectional views for each step of a method of manufacturing a display device according to an embodiment. FIGS. 12 to 14 are cross-sectional views schematically illustrating a method of manufacturing the display device of FIG. 5, which are briefly shown for convenience of description and a detailed symbol is omitted.

Referring to FIG. 12, an adhesive material layer ADL′ may be provided on the display panel DP. The adhesive material layer ADL′ may be applied on the display panel DP in a liquid state. For example, a viscosity of the adhesive material layer ADL′ at room temperature (e.g., in a range of about 20° C. to about 25° C.) may be in a range of about 1 cps to about 30 cps, but is not limited thereto.

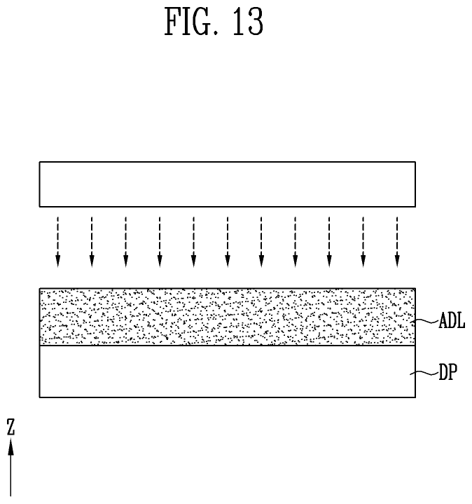

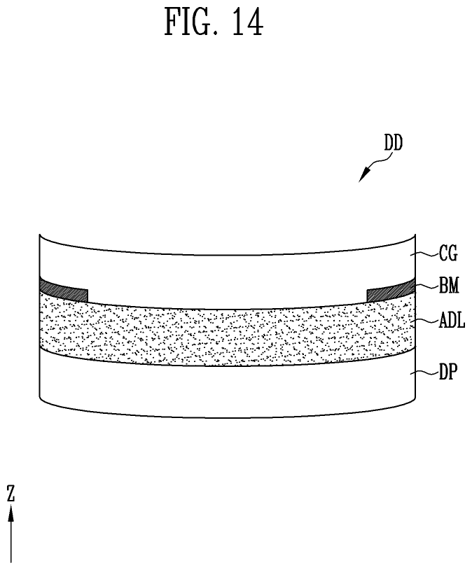

Referring to FIG. 13, the adhesive material layer ADL′ (e.g., refer to FIG. 12) may be cured to form the adhesive layer ADL. The adhesive material layer ADL′ may be cured in an exposed state before the light blocking layer BM (e.g., refer to FIG. 14) and/or the cover layer CG (e.g., refer to FIG. 14) are bonded. For example, curing of the adhesive material layer ADD may be completed before the light blocking layer BM and/or the cover layer CG are bonded to form the adhesive layer ADL of which adhesiveness is manifested.

In an embodiment, the adhesive layer ADL may be formed by curing the adhesive material layer ADD by irradiating ultraviolet light onto the adhesive material layer ADL′. For example, the adhesive material layer ADL′ may include a photocurable acrylic resin, a photoinitiator, a coupling agent, a radical generator, and a solvent. Detailed descriptions related to the photoinitiator, the coupling agent, the radical generator, and the solvent are omitted. According to an embodiment, the adhesive material layer ADL′ may include a thermosetting acrylic resin, a thermosetting agent, a coupling agent, and a solvent. Detailed descriptions related to the thermosetting acrylic resin, the thermosetting agent, the coupling agent, and the solvent are omitted.

The modulus of the adhesive layer ADL at room temperature may be in a range of about 10³ Pa to about 10⁶ Pa. The peel strength of the adhesive layer ADL at room temperature may be about 2,000 gf/in or greater. The surface curing rate of the adhesive layer ADL may be about 85% or greater. The deep curing rate of the adhesive layer ADL may be about 85% or greater. For example, the adhesive layer ADL may be in a semi-solid state.

Referring to FIG. 14, the light blocking layer BM and/or the cover layer CG may be adhered on the adhesive layer ADL. In case that a surface and/or another surface of the cover layer CG includes a curved surface, a surface and/or another surface of the adhesive layer ADL adhered or coupled thereto may include a curved surface corresponding to the curved surface of the cover layer CG. A surface and/or another surface of the display panel DP may include a curved surface corresponding to the curved surface of the cover layer CG. However, the disclosure is not limited thereto, and as shown in FIG. 6, a surface and/or another surface of the cover layer CG may include a flat surface. A surface and/or another surface of the adhesive layer ADL bonded or coupled to the cover layer CG may include a flat surface corresponding to the flat surface of the cover layer CG. A surface and/or another surface of the display panel DP may include a flat surface corresponding to the flat surface of the cover layer CG.

Differently from a general optical clear resin (OCR), the adhesiveness of the adhesive layer ADL according to an embodiment may be manifested before the cover layer CG is bonded, and thus a bonding defect or an air bubble may be prevented from occurring even though the cover layer CG includes a curved surface. Since a curing process is not performed after the light blocking layer BM is formed on the adhesive layer ADL, discoloration of the light blocking layer BM due to ultraviolet light or heat in the curing process may be prevented as described above. The adhesive layer ADL of the embodiment may be applied to the display device DD, and cost may be reduced compared to a display device including an expensive optical clear adhesive (OCA).

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
providing an adhesive material layer on a display panel;
curing the adhesive material layer to form an adhesive layer;
providing a cover layer on the adhesive layer; and
adhering the cover layer to the adhesive layer,
wherein a modulus of the adhesive layer at room temperature is in a range of about 10³ Pa to about 10⁶ Pa.

2. The method of claim 1, wherein the cover layer includes a curved surface.

3. The method of claim 1, wherein a viscosity of the adhesive material layer is in a range of about 1 cps to about 30 cps at room temperature.

4. The method of claim 1, wherein a peel strength of the adhesive layer at room temperature is about 2,000 gf/in or greater.

5. The method of claim 1, wherein a surface curing rate of the adhesive layer is about 85% or greater.

6. The method of claim 1, wherein a deep curing rate of the adhesive layer is about 85% or greater.

7. The method of claim 1, wherein the adhesive material layer is provided on the display panel in a liquid state.

8. The method of claim 1, wherein the adhesive layer is in a semi-solid state.

9. The method of claim 1, wherein the adhesive material layer is cured in an exposed state.

10. The method of claim 1, further comprising:
forming a light blocking layer on the display panel.

11. The method of claim 1, wherein the curing of the adhesive material layer comprises irradiating an ultraviolet light onto the adhesive material layer.

12. The method of claim 1, wherein the curing of the adhesive material layer comprises applying a heat to the adhesive material layer.

13. A display device comprising:
a display panel;
an adhesive layer on the display panel;
a cover layer on the adhesive layer; and
a light blocking layer between the adhesive layer and the cover layer,
wherein a surface curing rate of a first area of the adhesive layer overlapping the light blocking layer in a plan view is substantially equal to a surface curing rate of a second area of the adhesive layer which is not overlapping the light blocking layer in a plan view.

14. The display device of claim 13, wherein the cover layer includes a curved surface.

15. The display device of claim 13, wherein a modulus of the adhesive layer is in a range of about 10³ Pa to about 10⁶ Pa at room temperature.

16. The display device of claim 13, wherein a peel strength of the adhesive layer at room temperature is about 2,000 gf/in or greater.

17. The display device of claim 13, wherein a surface curing rate of the adhesive layer is about 85% or greater.

18. The display device of claim 13, wherein the adhesive layer is in a semi-solid state.

19. The display device of claim 13, wherein the adhesive material layer comprises a photocurable acrylic resin, a photoinitiator, a coupling agent, a radical generator, and a solvent.

20. The display device of claim 13, wherein the adhesive material layer comprises a thermosetting acrylic resin, a heat curing agent, a coupling agent, and a solvent.
